(19) United States
(12) Patent Application Publication
(10) Pub. No.: US 2024/0311222 A1
(43) Pub. Date: Sep. 19, 2024

(54) COMPUTER MEMORY HARDWARE CORRECTION USING BASELINE WANDER

(71) Applicant: INTERNATIONAL BUSINESS MACHINES CORPORATION, ARMONK, NY (US)

(72) Inventors: Matthew Doyle, Chatfield, MN (US); Patrick Fiske, Austin, TX (US); Rodolfo Lopez, Austin, TX (US); Sneha U. Kadam, Austin, TX (US)

(21) Appl. No.: 18/182,448

(22) Filed: Mar. 13, 2023

(51) Int. Cl. G06F 11/20; G06F 11/07; G06F 11/22

(52) U.S. Cl. CPC G06F 11/2023; G06F 11/076; G06F 11/0772; G06F 11/2263

(57) ABSTRACT

A method, computer system, and a computer program product for computer memory structural analysis are provided. A processor receives test results that indicate baseline interface voltage level that is from a transient data transmission and is measured at the computer memory. In response to detecting, via the processor, that the test results indicate a baseline wander for the baseline interface voltage level of the computer memory, the processor generates, based on the baseline wander, an identification of an associated structural communication flaw of the computer memory and a compensation recommendation for compensative for the structural flaw. The processor transmits the compensation recommendation for presentation of the compensation recommendation.

### BACKGROUND

The present invention relates generally to the field of computer memory hardware testing and repair.

### SUMMARY

According to one exemplary embodiment, a computer-implemented method for computer memory structural analysis is provided. A processor receives test results that indicate baseline interface voltage level that is from a transient data transmission and is measured at the computer memory. In response to detecting, via the processor, that the test results indicate a baseline wander for the baseline interface voltage level of the computer memory, the processor generates, based on the baseline wander, an identification of an associated structural communication flaw of the computer memory and a compensation recommendation for compensative for the structural flaw. The processor transmits the compensation recommendation for presentation of the compensation recommendation. A computer system and computer program product corresponding to the above method are also disclosed herein.

### BRIEF DESCRIPTION OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1A illustrates a baseline wander-based computer memory structure correction environment according to at least one embodiment;

FIG. 1B is an operational flowchart illustrating a baseline wander-based computer memory structure correction process according to at least one embodiment;

FIG. 2 illustrates a view of baseline wander measurements involved in the baseline wander-based computer memory structure correction process shown in FIG. 1B according to at least some embodiments;

FIG. 3 illustrates a machine learning training portion for training a machine learning model to be used in at least one embodiment of the baseline wander-based computer memory structure correction process shown in FIG. 1B; and

FIG. 4 is a block diagram illustrating a computer environment with multiple computer systems in which baseline wander-based computer memory structure correction process described for FIG. 1B may be performed and/or in which the machine learning training portion described for FIG. 3 may be implemented.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

The following described exemplary embodiments provide a system, a method, and a computer program product for computer memory structural analysis and, if needed, repair. Computer memory typically undergoes rigorous assembly-level margin testing before being shipped from a manufacturing facility. By pinpointing a root structural cause of memory failure, the present embodiments remove a need for extensive failure analysis on many computer memories. Such failure analysis has in the past required shipping of the failing memory to another location, physical inspection of the computer memory that is being tested, memory characterization to locate a root cause, margin testing and/or signal integrity testing, extended memory exerciser runs, repetitive power cycling, and/or hardware replacement which can be expensive and time-consuming. The present embodiments overcome these traditional challenges of debugging an assembled but non-optimally functioning computer memory. The present embodiments enable mitigation and/or compensating techniques to be applied so that computer memory boards that are assembled but with faults may be corrected to be functional. The present embodiments implement baseline wander testing to detect where, when, and which express link lane of the computer memory has failed.

The present embodiments include analyzing computer memory structure by analyzing a baseline interface voltage level of the computer memory and any baseline wander detected in the voltage level. These baseline wander results may indicate a structural communication flaw of the computer memory such as insufficient interface margin, one or more failed data transmission lanes, or another functional concern based on parameters including a baseline interface voltage level and any baseline wander detected therein. In response to detecting the baseline wander, the processor generates based on the baseline wander an identification of an associated structural flaw and a compensation recommendation for compensating for the structural flaw. For example, the compensation recommendation may address margin or lack of function on one or more interface lanes/connections. In at least some embodiments, the processor compares baseline wander DC and AC voltage levels between multiple lanes of the computer memory, e.g., between lane 0 and lane n, and then compensates, as needed. The compensating recommendation may be based on user or specification-defined deviation tolerances. The compensating recommendation may include actions such as disabling effected data lanes and enabling spare data lanes.

Baseline wander as used in the present disclosure refers to a drift in a time-varying voltage waveform within an alternating current-coupled system. High-frequency transient data is passed through an interface, e.g., a serial or parallel interface, of a computer memory system. The direct current component of the data is removed between printed circuit boards and/or between systems across which the interface traverses. Baseline wander is a way to describe long-term drift in the mean voltage level of a time-varying waveform. The present embodiments harness, for detection, identification, and mitigation/compensation purposes, the knowledge that the direct current drift associated with baseline wander is directly impacted by the value of the alternating current (AC) coupling. The present embodiments encompass detection of transient voltage drift resulting from data transmission lane capacitance variation and/or defect. AC-coupled memory, parallel, and serial interfaces suffer from errors which fail during manufacturing and at client environments. When these errors are uncorrectable, physical hardware inspection has traditionally been required. One common cause of link fail is associated with an incorrect value and/or a poor assembly/electrical attach of discrete AC coupling capacitors. The present embodiments help avoid the physical inspection and/or manual measurements that were typically required for corrective action of the problematic computer memory that was assembled.

Baseline wander is a way to describe long-term drift (i.e., wander) in the mean voltage level of a time-varying waveform. Peak-to-peak values of the alternating current (AC) level is monitored and utilized. AC-coupled data transmission lanes such as high speed serial (HSS) and some memory interfaces utilize series capacitors which eliminate a specific DC value. Variation in DC-blocking capacitor values directly impacts baseline wander levels as indicated in discrete values and/or parasitic values that may occur due to improper attachment. The present embodiments utilize a baseline wander measurement and confirmation to detect when and which lane(s) suffer from AC coupling and/or assembly concerns. The present embodiments may implement testing in situ for the computer memory in its assembled position. In response to detecting baseline wander in a computer memory that is being tested, a recommendation for appropriate corrective action is generated and transmitted for display and in at least some embodiments carried out. Machine learning may be used to characterize expected versus actual transient AC data transmission levels based on baseline wander measurements on a lane-per-lane basis for the computer memory. One, some, or all of the lanes may be analyzed. The machine learning model may be trained to associate particular baseline wander values and/or patterns with particular structural communication flaws in the computer memory. Generating a compensation recommendation may include inputting the voltage level test results into a machine learning model and receiving output from the machine learning model that is generated in response to the inputting of the test results. The output may include an identification of a computer memory structural communication flaw that is associated with the baseline wander measurements. The appropriate corrective action may be carried out with or without machine learning. Baseline Wander deviations sampled across all interface lanes are compared to specific lane failure data. The process allows the creation of an automated interface for failure analysis which would otherwise entail physical oscilloscope measurements. In some embodiments, a baseline wander-based computer memory correction program stores a matching data table for matching and/or associating (1) particular baseline wander measurements with (2) one or more communication structural flaws in the computer memory that are associated with the particular baseline wander measurements. The matching data table may in those embodiments be used by receiving baseline wander measurements as input and then using them to retrieve and provide an identification of the associated communication structural flaw that is matched in the matching data table with those baseline wander measurements. The matching data table may additionally match and/or associate a structural remedy for compensating for the associated communication structural flaw.

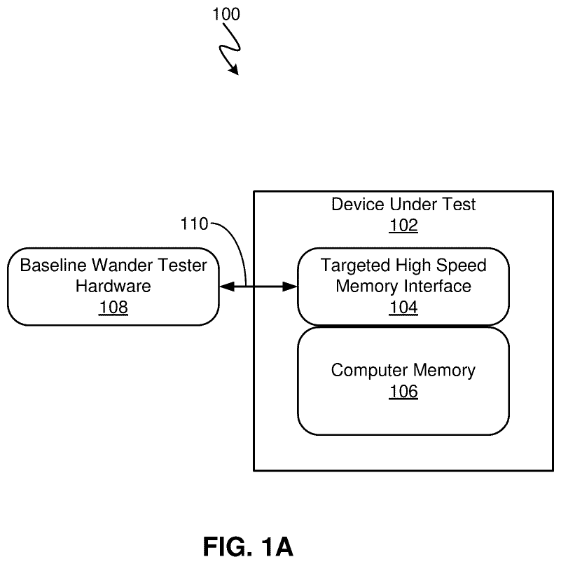

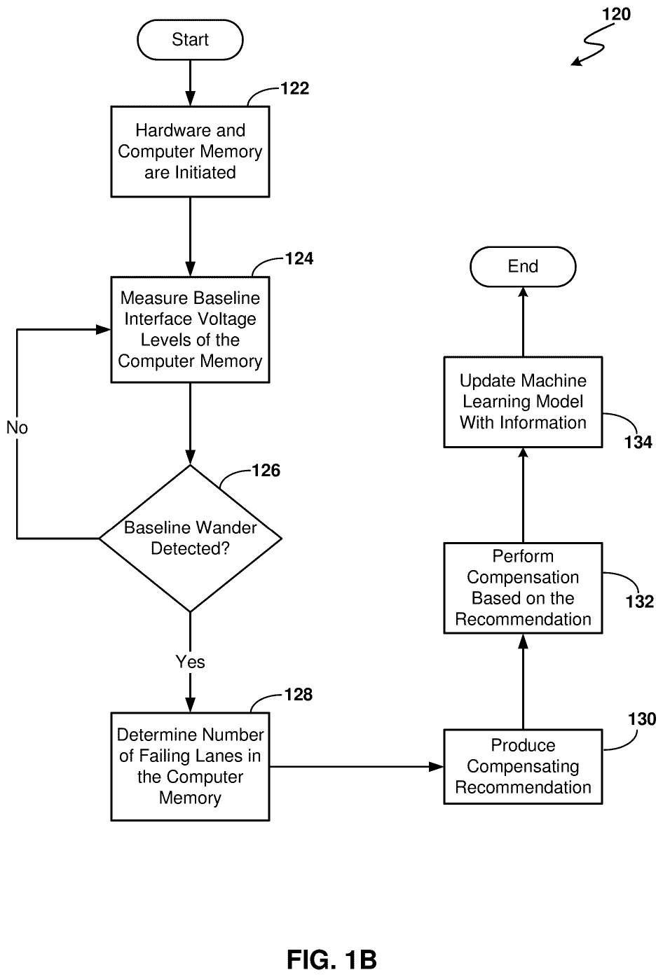

FIG. 1A illustrates a baseline wander-based computer memory structure correction environment 100 according to at least one embodiment in which the present embodiments may be implemented. Within the baseline wander-based computer memory structure correction environment 100, a device under test 102 which includes a computer memory 106 and a targeted high speed memory interface 104 is present. Baseline wander tester hardware 108 may create a physical connection 110 with the targeted high speed memory interface 104 in order to apply current to the device under test 102 and to test the targeted high speed memory interface 104 and the computer memory 106.

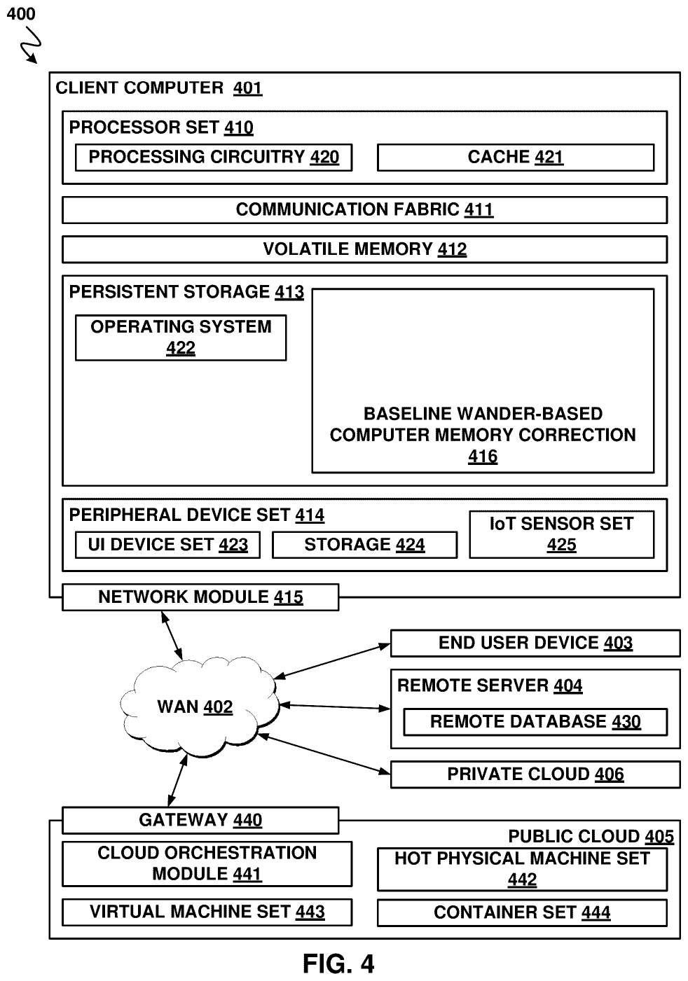

The computer memory 106 may be part of a motherboard of the device under test 102 which may be a server that has a processing layer to which a cable may be connected. Firmware of the server may provide some utilities on that limited shell that generate custom utilities that can probe into the electronic buffers and the components. The device under test 102 may include network adapter ports assigned to the processing layer. The physical connection 110 may be obtained using the network adapter ports to access the targeted high speed memory interface 104. The current provided to perform the testing may be generated via the baseline wander tester hardware 108 and/or via the device under test 102. The baseline wander tester hardware 108 receives test results of signals that are applied to the device under test 102. The baseline wander tester hardware 108 may communicate in a wired or wireless manner with a computer 401 shown in FIG. 4 which includes baseline wander-based computer memory correction program 416.

Referring now to FIG. 1B, an operational flowchart is shown that illustrates a baseline wander-based computer memory structure correction process 120 according to at least one embodiment. The components shown in FIG. 1A may be involved in the baseline wander-based computer memory structure correction process 120 shown in FIG. 1B.

In step 122 of the baseline wander-based computer memory structure correction process 120 shown in FIG. 1B, the hardware and computer memory are initiated. The initiation of step 122 includes finding the computer memory to be tested and turning on the hardware that will perform the test and/or the device under test 102 so that the system is on and functional. Thus, the step 122 may, for example, include accessing the device under test 102, physically connecting the baseline wander tester hardware 108 to the device under test 102, and turning on the baseline wander tester hardware 108. The computer memory that is to be tested may in an assembled state, e.g., in a recently assembled state before being shipped for an order.

In step 124 of the baseline wander-based computer memory structure correction process 120 shown in FIG. 1B, baseline interface voltage levels of the computer memory are measured. This measurement of step 124 is performed with respect to the computer memory that is initiated in step 122. The interface whose voltage level is being tested in at least some embodiments is an AC coupling of the computer memory that is being examined. The AC coupling is a DC blocking capacitor which blocks the DC portion of a signal and allows the AC portion of the signal to pass through. The blocking capacitor may normalize the signal to a mean of zero. The voltage may be measured using a voltmeter that is part of the automated test equipment, e.g., that is part of the baseline wander tester hardware 108 and/or part of the device under test 102.

The voltage test of step 122 may be initiated by a user interacting with a graphical user interface on an input/output device, e.g., a display screen and/or a keyboard, at the baseline wander tester hardware 108 and/or the computer 401 shown in FIG. 4. The graphical user interface may be generated via the baseline wander-based computer memory correction program 416 that is stored in the persistent storage 413 of the computer 401 and/or via software stored in the baseline wander tester hardware 108. In other embodiments, to perform the voltage test the baseline wander-based computer memory correction program 416 communicates with software that is hosted elsewhere in the computer 401 or in a different computer such as remote server 404 or in the baseline wander tester hardware 108. When the computer 401 is at a physical position that is different from and not adjacent to the position of the baseline wander tester hardware 108, the communication may occur via a communication network such as the wide-area network 402. The graphical user interface may allow a user to choose a parameter such as voltage to test and to begin the test.

The test that is performed in step 124 may include applying voltage to the computer memory, e.g., to the targeted high speed memory interface 104 of the computer memory 106 within the device under test 102. A time-varying voltage waveform within an alternating current-coupled system may be captured. High-frequency transient data may be passed through the targeted high speed memory interface 104 which may, for example, be a serial or parallel interface. The direct current component of the data is removed at the interface.

In step 126 of the baseline wander-based computer memory structure correction process 120 shown in FIG. 1B, a determination is made whether baseline wander is detected. This detection determination occurs by using the voltage measurement that was performed in step 124. If the detection determination is affirmative in that baseline wander is detected, the baseline wander-based computer memory structure correction process proceeds to step 128. If the detection determination is negative in that baseline wander is not detected, the baseline wander-based computer memory structure correction process proceeds back to step 124 for a repeat of steps 124 and 126 with respect to the same computer memory or a different computer memory.

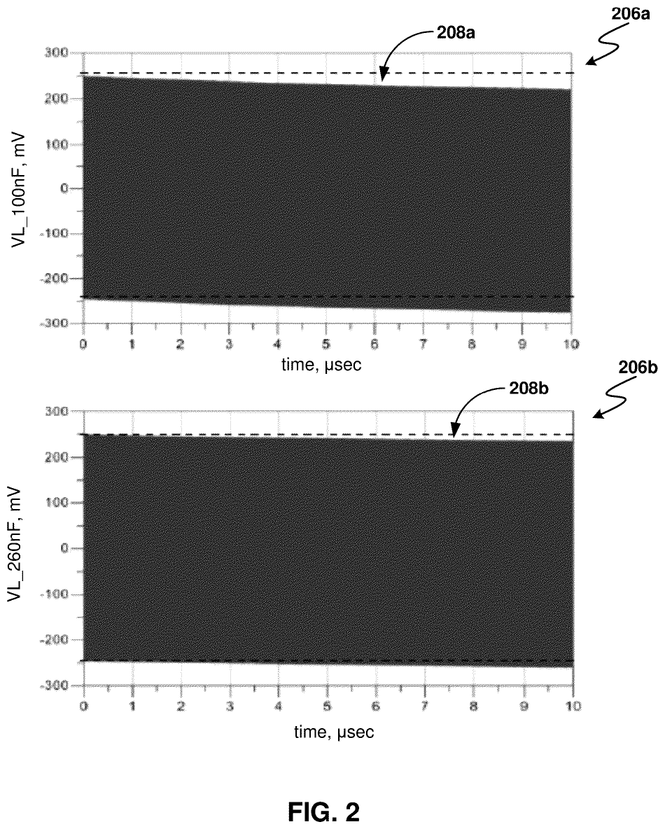

The time-varying voltage waveform captured from the voltage test is analyzed in step 126 in order to check for any drift within the time-varying voltage waveform. FIG. 2 described below provides views of voltage level test results which may be analyzed via the baseline wander-based computer memory correction program 416 in order to detect baseline wander.

In at least some embodiments, the determination of step 126 is made with respect to a baseline wander threshold value. If the measured baseline wander equals and/or exceeds the baseline wander threshold value, the determination of step 126 may be deemed affirmative. If the measured baseline wander does not exceed the baseline wander threshold value, the determination of step 126 may be deemed affirmative. The baseline wander is the variation in the average value of logic low and high for the voltage signal. The average value will drift with capacitance variance. A change in capacitance level of the capacitor may affect an amount of deviation and/or drift that occurs. A change from 10 pF to 100 pF (picofarad) capacitance level of the capacitor may result in 25 mV to 50 mV deviation in the voltage measurement.

In some instances, voltage level measurements illustrate the repeating test bit stream alternating between long run length bits and clock-like bits. The test bit stream may include more one values than zero values. A running DC balance may increase as the test pattern repeats over a long time period. A measured current level at a capacitor of the interface may drift. Some voltage level measurements may show swing waveforms and indicate baseline drifts/wander at the direct current level. Peak-to-peak voltage levels may vary across all of the sampled lanes and may drift with time. Baseline wander for an AC coupling has been referred to as DC wander because with the baseline wander a virtual DC level shift occurs. AC-coupled interfaces use DC-blocking capacitors which remove the DC level, creating a peak-to-peak voltage excursion centered at 0 V. Performing this removal and centering allows data transfer between devices which operate at different DC bias. Imperfections or errors associated with the capacitors can allow wander which shifts the center voltage and can be thought of as DC. This shift may constitute a “virtual” DC level shift but primarily refers to a shift in peak-to-peak values in the AC current.

FIG. 2 shows views of voltage level test results including a first test results view 206a and a second test results view 206b. The measurement results in the first and second test results views 206a, 206b show the voltage level indicated on the y-axis of the graphs and the time value indicated on the x-axis of the graphs. The x-axis time value in the voltage level measurement results of the first test results view 206a and a second test results view 206b is in microseconds (μsec). The first tests results view 206a shown in FIG. 2 shows results of the voltage test performed on a 100 nF capacitance computer memory. The second test results view 206b shown in FIG. 2 shows results of the voltage test performed on a 260 nF capacitance computer memory. Gradual DC level shift from the running DC balance is clearly demonstrated in waveform swing envelopes. The first baseline wander 208a and the second baseline wander 208b are visible in the first test results view 206a and a second test results view 206b, respectively, as the average values drift from the constant maximum and minimum voltage values. These first and second baseline wanders 208a, 208b, respectively, shown in FIG. 2 are examples of baseline wander values exceeding a baseline wander threshold value.

In at least some embodiments the determination in step 126 is made in an automated manner via the baseline wander-based computer memory correction program 416 that is stored on the computer 401. The baseline wander-based computer memory correction program 416 itself may generate the voltage level graphs and/or may receive the graphs from another module or software component or from the baseline wander tester hardware 108. The baseline wander threshold levels may be preselected by a user and/or predetermined by the baseline wander-based computer memory correction program 416 based on learned knowledge from testing of other computer memories performed previously.

In step 128 of the baseline wander-based computer memory structure correction process 120 shown in FIG. 1B, a number of failing lanes in the computer memory is determined. The baseline wander-based computer memory correction program 416 may perform this determination of step 128 based on knowledge of the bus and lane design of the computer memory and using the baseline wander and voltage levels determined in the previous steps. The baseline wander being detected may indicate a lack of margin and/or lack of electrical function on all or some of the lanes of the overall bus. The previous testing may have provided results which characterize expected versus actual voltage baseline on a lane-per-lane basis. Baseline wander deviations sampled across all interface lanes are compared to specific lane failure data. This comparison may constitute a failure analysis with an automated interface. The results and characterization from previous testing may be stored in memory hosted by the baseline wander-based computer memory correction program 416 and/or accessible by the baseline wander-based computer memory correction program 416.

In step 130 of the baseline wander-based computer memory structure correction process 120 shown in FIG. 1B, a compensating recommendation is produced. The compensating recommendation is based on remedying the physical bus failure that was indicated and identified via the detection and analysis of the baseline wander of the previous steps. Potential corrective actions may be learned from previous testing and may be stored in memory hosted by the baseline wander-based computer memory correction program 416 and/or accessible by the baseline wander-based computer memory correction program 416. The baseline wander-based computer memory correction program 416 may match a baseline wander value to an appropriate corrective action, with different values being associated with different corrective actions. In some embodiments, the production of the compensating recommendation is produced using a machine learning model which is trained to generate a corrective action based on receiving baseline wander results and bus structure as inputs.

The compensating recommendation may include rerouting of a defective lane to a spare lane and/or to a secondary lane. The rerouting of physical lanes may occur through a micro-electro-mechanical system device or other technique. The compensating recommendation may alternatively and/or additionally include identifying a defective lane and/or a defective component by the setting of a flag bit. The compensating recommendation may alternatively and/or additionally include running the computer memory in a degraded mode with only some of the lanes being active, e.g., with fifty percent, e.g., four out of eight possible lanes, being active. The degrade mode may include operating the computer memory with a reduced number of total operational data transmission lanes as compared to an initial number of data transmission lanes. The compensating recommendation may include resending data for intermittent lanes.

In at least some embodiments, the production of step 130 may include a transmission of the recommendation for presentation to a user. For example, the baseline wander-based computer memory correction program 416 may transmit the presentation through the computer 401 for visual display on a computer display screen of the computer 401 and/or for audible display through an audio speaker of the computer 401.

In step 132 of the baseline wander-based computer memory structure correction process 120 shown in FIG. 1B, a compensation is performed based on the recommendation. The recommendation refers to the compensating recommendation that was produced in step 130. The compensation that is performed may include rerouting of a defective lane to a spare lane and/or to a secondary lane. The compensation may alternatively and/or additionally include setting of one or more flag bits to respectively identify the defective lane and/or defective component. The compensation may alternatively and/or additionally include running the computer memory in a degraded mode with only some of the lanes being active. The compensation recommendation in some embodiments occurs via the baseline wander-based computer memory correction program 416 automatically generating compensation performance instructions to cause automated equipment to carry out the computer memory correction. The compensation recommendation in some embodiments occurs via a user manually following the compensation recommendations to carry out the computer memory correction.

In step 134 of the baseline wander-based computer memory structure correction process 120 shown in FIG. 1B, a machine learning model is updated with information. This information refers to the information gained in this iteration of the baseline wander-based computer memory structure correction process 120 and particularly with respect to the baseline wander testing and compensation action taken with respect to the tested computer memory. The baseline wander-based computer memory correction program 416 may provide the information to a machine learning model hosted at the baseline wander-based computer memory correction program 416 at the computer 401 or to a machine learning model that is accessible to the baseline wander-based computer memory correction program 416. The machine learning model once updated may be used in subsequent iterations for improved baseline wander detection, improved production of compensating recommendations, and improved techniques for execution of the compensating recommendation.

After step 134, the baseline wander-based computer memory structure correction process 120 may end. The baseline wander-based computer memory structure correction process 120 may be repeated to test and correct hardware issues in other computer memories.

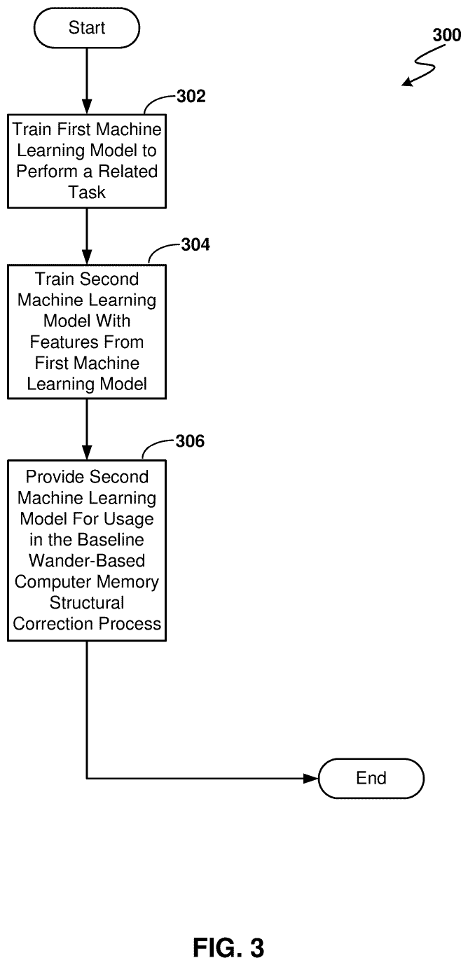

FIG. 3 illustrates a machine learning training process 300 for training a machine learning model to be used in at least one embodiment of the baseline wander-based computer memory structure correction process 120 shown in FIG. 1B.

In step 302 of the machine learning training process 300 shown in FIG. 3, a first machine learning model is trained to perform a related task. The related task refers to a test on a computer memory but different from the baseline interface voltage level testing to examine baseline wander as was described above with respect to FIGS. 1 and 2. In one example, a first machine learning model is trained on results of clock skew determination and clock skew mitigation performed on the one or more other computer memories.

In step 304 of the machine learning training process 300 shown in FIG. 3, a second machine learning model is trained with features from the first machine learning model. The first machine learning model refers to that model trained in step 302. In step 304, a second machine learning model may receive node weights and/or layers from the first machine learning model.

In step 306 of the machine learning training process 300 shown in FIG. 3, the second machine learning model is provided for usage in the baseline wander-based computer memory structural correction process 120 that was described previously with respect to FIG. 1B. This second machine learning model refers to that model trained in step 304. The trained second machine learning model may be used in steps 106, 108, and/or 110 of the baseline wander-based computer memory structural correction process 120. Specifically, the second machine learning model may be used to detect baseline wander, to determine a number and location of one or more failing lanes in a bus of the computer memory, and/or to produce a compensating recommendation for appropriately remedying any lane, components, interface, and/or other structural defect of the computer memory.

It may be appreciated that FIGS. 1A, 1B, 2, and 3 provide only illustration of certain embodiments and/or features and do not imply any limitations with regard to how different embodiments may be implemented. Many modifications to the depicted embodiment(s), e.g., to a sequence of steps or components that are depicted, may be made based on design and implementation requirements.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example. again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one. or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 400 shown in FIG. 4 contains an example of an environment for the execution of at least some of the computer code involved in performing the inventive methods, such as baseline wander-based computer memory correction program 416. In addition to baseline wander-based computer memory correction program 416, computing environment 400 includes, for example, computer 401, wide area network (WAN) 402, end user device (EUD) 403, remote server 404, public cloud 405, and private cloud 406. In this embodiment, computer 401 includes processor set 410 (including processing circuitry 420 and cache 421), communication fabric 411, volatile memory 412, persistent storage 413 (including operating system 422 and multilingual machine learning model pretraining 416, as identified above), peripheral device set 414 (including user interface (UI) device set 423, storage 424, and Internet of Things (IoT) sensor set 425), and network module 415. Remote server 404 includes remote database 430. Public cloud 405 includes gateway 440, cloud orchestration module 441, host physical machine set 442, virtual machine set 443, and container set 444.

COMPUTER 401 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 430. As is well understood in the art of computer technology, and depending upon the technology, performance of a computer-implemented method may be distributed among multiple computers and/or between multiple locations. On the other hand, in this presentation of computing environment 400, detailed discussion is focused on a single computer, specifically computer 401, to keep the presentation as simple as possible. Computer 401 may be located in a cloud, even though it is not shown in a cloud in FIG. 4. On the other hand, computer 401 is not required to be in a cloud except to any extent as may be affirmatively indicated.

PROCESSOR SET 410 includes one, or more, computer processors of any type now known or to be developed in the future. Processing circuitry 420 may be distributed over multiple packages, for example, multiple, coordinated integrated circuit chips. Processing circuitry 420 may implement multiple processor threads and/or multiple processor cores. Cache 421 is memory that is located in the processor chip package(s) and is typically used for data or code that should be available for rapid access by the threads or cores running on processor set 410. Cache memories are typically organized into multiple levels depending upon relative proximity to the processing circuitry. Alternatively, some, or all, of the cache for the processor set may be located “off chip.” In some computing environments, processor set 410 may be designed for working with qubits and performing quantum computing.

Computer readable program instructions are typically loaded onto computer 401 to cause a series of operational steps to be performed by processor set 410 of computer 401 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 421 and the other storage media discussed below. The program instructions, and associated data, are accessed by processor set 410 to control and direct performance of the inventive methods. In computing environment 400, at least some of the instructions for performing the inventive methods may be stored in multilingual machine learning model pretraining 416 in persistent storage 413.

COMMUNICATION FABRIC 411 is the signal conduction path that allows the various components of computer 401 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 412 is any type of volatile memory now known or to be developed in the future. Examples include dynamic type random access memory (RAM) or static type RAM. Typically, volatile memory 412 is characterized by random access, but this is not required unless affirmatively indicated. In computer 401, the volatile memory 412 is located in a single package and is internal to computer 401, but, alternatively or additionally, the volatile memory may be distributed over multiple packages and/or located externally with respect to computer 401.

PERSISTENT STORAGE 413 is any form of non-volatile storage for computers that is now known or to be developed in the future. The non-volatility of this storage means that the stored data is maintained regardless of whether power is being supplied to computer 401 and/or directly to persistent storage 413. Persistent storage 413 may be a read only memory (ROM), but typically at least a portion of the persistent storage allows writing of data, deletion of data and re-writing of data. Some familiar forms of persistent storage include magnetic disks and solid state storage devices. Operating system 422 may take several forms, such as various known proprietary operating systems or open source Portable Operating System Interface-type operating systems that employ a kernel. The code included in multilingual machine learning model pretraining 416 typically includes at least some of the computer code involved in performing the inventive methods.

PERIPHERAL DEVICE SET 414 includes the set of peripheral devices of computer 401. Data communication connections between the peripheral devices and the other components of computer 401 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 423 may include components such as a display screen, speaker, microphone, wearable devices (such as goggles and smart watches), keyboard, mouse, printer, touchpad, game controllers, and haptic devices. Storage 424 is external storage, such as an external hard drive, or insertable storage, such as an SD card. Storage 424 may be persistent and/or volatile. In some embodiments, storage 424 may take the form of a quantum computing storage device for storing data in the form of qubits. In embodiments where computer 401 is required to have a large amount of storage (for example, where computer 401 locally stores and manages a large database) then this storage may be provided by peripheral storage devices designed for storing exceptionally large amounts of data, such as a storage area network (SAN) that is shared by multiple, geographically distributed computers. IoT sensor set 425 is made up of sensors that can be used in Internet of Things applications. For example, one sensor may be a thermometer and another sensor may be a motion detector.

NETWORK MODULE 415 is the collection of computer software, hardware, and firmware that allows computer 401 to communicate with other computers through WAN 402. Network module 415 may include hardware, such as modems or Wi-Fi signal transceivers, software for packetizing and/or de-packetizing data for communication network transmission, and/or web browser software for communicating data over the internet. In some embodiments. network control functions and network forwarding functions of network module 415 are performed on the same physical hardware device. In other embodiments (for example, embodiments that utilize software-defined networking (SDN)), the control functions and the forwarding functions of network module 415 are performed on physically separate devices, such that the control functions manage several different network hardware devices. Computer readable program instructions for performing the inventive methods can typically be downloaded to computer 401 from an external computer or external storage device through a network adapter card or network interface included in network module 415.

WAN 402 is any wide area network (for example, the internet) capable of communicating computer data over non-local distances by any technology for communicating computer data, now known or to be developed in the future. In some embodiments, the WAN 402 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 403 is any computer system that is used and controlled by an end user (for example, a customer of an enterprise that operates computer 401) and may take any of the forms discussed above in connection with computer 401. EUD 403 typically receives helpful and useful data from the operations of computer 401. For example, in a hypothetical case where computer 401 is designed to provide a natural language processing result to an end user, this result would typically be communicated from network module 415 of computer 401 through WAN 402 to EUD 403. In this way, EUD 403 can display, or otherwise present, the result to an end user. In some embodiments, EUD 403 may be a client device, such as thin client, heavy client, mainframe computer, desktop computer and so on.

REMOTE SERVER 404 is any computer system that serves at least some data and/or functionality to computer 401. Remote server 404 may be controlled and used by the same entity that operates computer 401. Remote server 404 represents the machine(s) that collect and store helpful and useful data for use by other computers, such as computer 401. For example, in a hypothetical case where computer 401 is designed and programmed to provide a recommendation based on historical data, then this historical data may be provided to computer 401 from remote database 430 of remote server 404.

PUBLIC CLOUD 405 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 405 is performed by the computer hardware and/or software of cloud orchestration module 441. The computing resources provided by public cloud 405 are typically implemented by virtual computing environments that run on various computers making up the computers of host physical machine set 442, which is the universe of physical computers in and/or available to public cloud 405. The virtual computing environments (VCEs) typically take the form of virtual machines from virtual machine set 443 and/or containers from container set 444. It is understood that these VCEs may be stored as images and may be transferred among and between the various physical machine hosts, either as images or after instantiation of the VCE. Cloud orchestration module 441 manages the transfer and storage of images, deploys new instantiations of VCEs and manages active instantiations of VCE deployments. Gateway 440 is the collection of computer software, hardware, and firmware that allows public cloud 405 to communicate through WAN 402.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders. network shares, CPU power, and quantifiable hardware capabilities. However, programs running inside a container can only use the contents of the container and devices assigned to the container, a feature which is known as containerization.

PRIVATE CLOUD 406 is similar to public cloud 405, except that the computing resources are only available for use by a single enterprise. While private cloud 406 is depicted as being in communication with WAN 402, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 405 and private cloud 406 are both part of a larger hybrid cloud.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises,” “comprising,” “includes,” “including,” “has,” “have,” “having,” “with,” and the like, when used in this specification, specify the presence of stated features, integers, steps, operations, elements, and/or components, but does not preclude the presence or addition of one or more other features, integers, steps, operations, elements, components, and/or groups thereof.

The descriptions of the various embodiments of the present invention have been presented for purposes of illustration but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer-implemented method for computer memory structural analysis, the method comprising:
receiving, via a processor, test results that indicate baseline interface voltage level that is from a transient data transmission and is measured at the computer memory;
in response to detecting, via the processor, that the test results indicate a baseline wander for the baseline interface voltage level of the computer memory, generating via the processor and based on the baseline wander an identification of an associated structural communication flaw of the computer memory and a compensation recommendation for compensating for the structural flaw; and
transmitting, via the processor, the compensation recommendation for presentation of the compensation recommendation.

2. The method of claim 1, wherein the associated structural communication flaw comprises a number of failing lanes in the computer memory.

3. The method of claim 2, further comprising generating a recommendation to enable a respective flag for the one or more failing lanes of the computer memory.

4. The method of claim 1, further comprising comparing voltage levels between lanes of the computer memory, wherein the generating of the identification is further based on the voltage level comparison between the lanes.

5. The method of claim 1, wherein the compensation recommendation comprises a recommendation to reroute a defective lane of the computer memory to another lane of the computer memory.

6. The method of claim 1, wherein the compensation recommendation comprises a recommendation to operate the computer memory in a degraded mode.

7. The method of claim 6, wherein the degraded mode comprises operating the computer memory with a reduced number of total operational lanes.

8. The method of claim 1, wherein the generating the compensation recommendation comprises inputting the test results into a machine learning model and receiving output from the machine learning model that is generated in response to the inputting of the test results.

9. The method of claim 8, wherein the machine learning model was trained via data and structural analyses obtained from baseline interface voltage tests that were performed on one or more other computer memories.

10. The method of claim 8, wherein the machine learning model was trained via transfer learning from data obtained from tests on one or more other computer memories.

11. The method of claim 10, wherein results of clock skew determination and clock skew mitigation performed on the one or more other computer memories were related tasks used for the transfer learning for the machine learning model.

12. A computer system for computer memory structural analysis, the computer system comprising:
one or more processors, one or more computer-readable memories, one or more computer-readable tangible storage media, and program instructions stored on at least one of the one or more computer-readable tangible storage media for execution by at least one of the one or more processors to cause the computer system to:
receive test results that indicate baseline interface voltage level that is from a transient data transmission and is measured at the computer memory;
in response to detecting that the test results indicate a baseline wander for the baseline interface voltage level of the computer memory, generate based on the baseline wander an identification of an associated structural communication flaw of the computer memory and a compensation recommendation for compensating for the structural flaw; and
transmit the compensation recommendation for presentation of the compensation recommendation.

13. The computer system of claim 12, wherein the associated structural communication flaw comprises a number of failing lanes in the computer memory.

14. The computer system of claim 13, wherein the program instructions further cause the computer system to generate a recommendation to enable a respective flag for the one or more failing lanes of the computer memory.

15. The computer system of claim 12, wherein the program instructions further cause the computer system to compare voltage levels between lanes of the computer memory, wherein the generating of the identification is further based on the voltage level comparison between the lanes.

16. The computer system of claim 12, wherein the compensation recommendation comprises a recommendation to reroute a defective lane of the computer memory to another lane of the computer memory.

17. A computer program product for computer memory structural analysis, the computer program product comprising a computer-readable storage medium having program instructions embodied therewith, wherein the program instructions are executable by a processor to cause the processor to perform a method comprising:
receive test results that indicate baseline interface voltage level that is from a transient data transmission and is measured at the computer memory;
in response to detecting that the test results indicate a baseline wander for the baseline interface voltage level of the computer memory, generate based on the baseline wander an identification of an associated structural communication flaw of the computer memory and a compensation recommendation for compensating for the structural flaw; and
transmit the compensation recommendation for presentation of the compensation recommendation.

18. The computer program product of claim 17, wherein the associated structural communication flaw comprises a number of failing lanes in the computer memory.

19. The computer program product of claim 18, wherein the program instructions further cause the computer system to generate a recommendation to enable a respective flag for the one or more failing lanes of the computer memory.

20. The computer program product of claim 17, wherein the program instructions further cause the computer system to compare voltage levels between lanes of the computer memory, wherein the generating of the identification is further based on the voltage level comparison between the lanes.
